(19) United States
(12) Patent Application Publication
(10) Pub. No.: US 2024/0139887 A1
(43) Pub. Date: May 2, 2024

(54) BONDING SHEET

(71) Applicant: NITTO DENKO CORPORATION, Ibaraki-shi, Osaka (JP)

(72) Inventors: Ayumi NITTA, Ibaraki-shi, Osaka (JP); Masatoshi KATO, Ibaraki-shi, Osaka (JP); Naofumi KOSAKA, Ibaraki-shi, Osaka (JP)

(21) Appl. No.: 18/281,257

(22) PCT Filed: Mar. 7, 2022
(86) PCT No.: PCT/JP2022/009646

§ 371 Date: Sep. 8, 2023

(30) Foreign Application Priority Data
Mar. 9, 2021 (JP) 2021-037818
Sep. 29, 2021 (JP) 2021-159847

(51) Int. Cl. B23K 35/02; B23K 35/26; B23K 35/36; B23K 35/362; B23K 35/365

(52) U.S. Cl. CPC B23K 35/0233; B23K 35/264; B23K 35/3613; B23K 35/362; B23K 35/365; B23K 2101/36

(57) ABSTRACT

A bonding sheet according to the present invention contains a matrix resin; solder particles; and a fluxing agent. The bonding sheet has a surface with a surface roughness Sa of 2.5 μm or less.

### TECHNICAL FIELD

The present invention relates to a bonding sheet for solder bonding.

### BACKGROUND ART

In mounting of an electronic component on a wiring board, for example, a terminal of the wiring board and a terminal of the electronic component are solder-bonded. As a solder material supply for solder bonding, a bonding sheet containing a thermosetting resin and solder particles is known. Such technique for the bonding sheet is disclosed in, for example, Patent Document 1 below.

### CITATION LIST

### Patent Document

Patent Document 1: Japanese Unexamined Patent Publication No. 2015-044912

### SUMMARY OF THE INVENTION

### Problem to be Solved by the Invention

The bonding sheet for solder bonding is used, for example, as follows. First, a wiring board, a bonding sheet, and an electronic component are laminated in this order. The wiring board and the electronic component are temporarily bonded together via the bonding sheet in an arrangement in which a terminal of the wiring board and a terminal of the electronic component face each other. Then, a solder portion is formed between the facing terminals through a heating step. Specifically, the heating causes a thermosetting resin to soften once in the bonding sheet. Then, the solder particles are melted and aggregated, and gather between the facing terminals (self-alignment), so that curing of the thermosetting resin progresses around the solder material where the particles gather. The solder material where the particles gather between the facing terminals coagulates by subsequent lowering of the temperature, to form a solder portion. The thermosetting resin forms a cured resin portion around the solder portion.

The bonding sheet described in Patent Document contains flux particles. The flux particles melt and remove oxide films on the surfaces of the solder particles in the heating step. This removal of the oxide films makes the solder particles more likely to aggregate.

However, the flux particles in the bonding sheet cause unevenness on the surface of the bonding sheet. The larger the flux particles, the larger the surface unevenness of the bonding sheet. The larger the surface unevenness is, the weaker the adhesive strength of the bonding sheet to the wiring board and the electronic component is during the temporary bonding described above. Insufficient adhesive strength of the bonding sheet causes misalignment of the wiring board and the electronic component during the temporary bonding, which is not preferable. The bonding sheet for solder bonding is required to cause no such adhesion failure.

The present invention provides a bonding sheet suitable for suppressing adhesion failure to an adherend.

### Means for Solving the Problem

The present invention [1] includes a bonding sheet, containing a matrix resin; solder particles; and a fluxing agent, and having a surface with a surface roughness Sa of 2.5 μm or less.

The present invention [2] includes the bonding sheet described in [1], in which the fluxing agent is a solid carboxylic acid at 25° C.

The present invention [3] includes the bonding sheet described in [1] or [2], having a thickness of 30 μm or less.

The present invention [4] includes the bonding sheet described in any one of the above-described [1] to [3], having a tack change rate of −30% or more, the tack change rate from the same bonding sheet except for not containing the fluxing agent.

### Effects of the Invention

As described above, the bonding sheet of the present invention contains a matrix resin, solder particles, and a fluxing agent, and has a surface with a surface roughness Sa of 2.5 μm or less. Therefore, this bonding sheet is suitable for ensuring adhesive strength when bonded to the adherend, and thus is suitable for suppressing adhesive failure to the adherend.

### BRIEF DESCRIPTION OF THE DRAWINGS

FIG. 1 shows a cross-sectional schematic view of one embodiment of a bonding sheet of the present invention.

FIGS. 2A and 2B represent some steps in one embodiment of a production method of the bonding sheet of the present invention: FIG. 2A represents a coated film forming step, and FIG. 2B represents a drying step.

FIGS. 3A to 3C represent a process diagram of one example of a solder bonding method using the bonding sheet shown in FIG. 1: FIG. 3A represents a preparation step, FIG. 3B represents a lamination step, and FIG. 3C represents a heating step.

### DESCRIPTION OF THE EMBODIMENTS

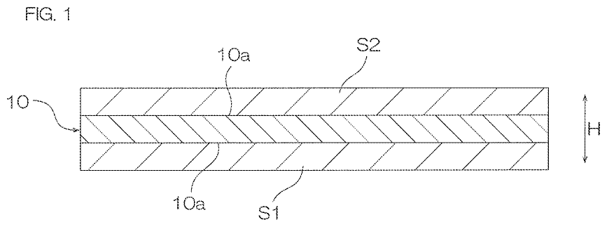

FIG. 1 shows a cross-sectional schematic view of a bonding sheet 10 as one embodiment of the bonding sheet of the present invention (a state in which the bonding sheet 10 is sandwiched between substrates S1 and S2 is illustrated). The bonding sheet 10 is a sheet for solder bonding and contains solder particles, a fluxing agent, and a matrix resin. The bonding sheet 10 has a sheet shape having a predetermined thickness and extends in a direction (plane direction) orthogonal to a thickness direction H. Also, the bonding sheet 10 may have a long sheet shape. When the bonding sheet 10 has a long sheet shape, it may have a roll form which is wound up. Or, the bonding sheet 10 may also have a single-sheet form.

Examples of the solder particles include solder materials containing no lead (lead-free solder) from the viewpoint of environmental suitability. Examples of the solder material include tin-bismuth-based alloys and tin-silver-based alloys. Examples of the tin-bismuth-based alloy include tin-bismuth alloys (Sn—Bi) and tin-bismuth-indium alloys (Sn—Bi—In). Examples of the tin-silver-based alloy include tin-silver alloys (Sn—Ag) and tin-silver-copper alloys (Sn—Ag—Cu). From the viewpoint of low temperature bonding, as the material for the solder particles, preferably, a tin-bismuth alloy and a tin-bismuth-indium alloy are used. These solder particles may be used alone or in combination of two or more.

A content ratio of the tin in the tin-bismuth-based alloy is, for example, 10% by mass or more, preferably 20% by mass or more, more preferably 25% by mass or more, and for example, 75% by mass or less, preferably 50% by mass or less, more preferably 30% by mass or less. A content ratio of the bismuth in the tin-bismuth-based alloy is, for example, 25% by mass or more, preferably 55% by mass or more, and for example, 90% by mass or less, preferably 75% by mass or less. When the tin-bismuth-based alloy contains indium, a content ratio of the indium is, for example, 8% by mass or more, preferably 12% by mass or more, more preferably 18% by mass or more, and for example, 30% by mass or less, preferably 25% by mass or less.

The solder material has a melting point (melting point of the solder particles) of, for example, 240° C. or less, preferably 200° C. or less, more preferably 180° C. or less, and for example, 70° C. or more, preferably 100° C. or more, more preferably 120° C. or more. The melting point of the solder material can be determined by differential scanning calorimetry (DSC) (the same applies to the melting point of a material of the fluxing agent to be described later).

Examples of a shape of the solder particle include spherical shapes, plate shapes, and needle shapes, and preferably, a spherical shape is used.

The solder particles have a particle size D₅₀ of preferably 7 μm or less, more preferably 6 μm or less, further more preferably 5 μm or less. These configurations are suitable for suppressing precipitation of the solder particles in a mixed composition (described later) adjusted during a production process of the bonding sheet 10, and therefore, are preferable to realize an excellent dispersion state of the solder particles in the bonding sheet 10 to be formed. The particle size D₅₀ of the solder particles relative to the thickness of the bonding sheet 10 is preferably 0.9 or less, more preferably 0.7 or less, further more preferably 0.5 or less. Such a configuration is preferable to thinly fabricate the bonding sheet 10 with its surface unevenness suppressed. In addition, these configurations regarding the smallness of the solder particles are preferable to form a minute solder portion corresponding to its thinness from the solder particles using the bonding sheet 10. From the viewpoint of appropriately forming the solder portion between objects to be solder-bonded, the particle size D₅₀ of the solder particles is preferably 10 nm or more. The particle size D₅₀ of the solder particles is the median size in the volume-based particle size distribution (the particle size where the volume cumulative frequency thereof reaches 50% from the smaller diameter side), and is determined based on the particle size distribution obtained by, for example, laser diffraction and scattering (the same applies to the particle size D₅₀ of flux particles to be described later).

The solder particle content in the bonding sheet 10 is preferably 50 parts by mass or more, more preferably 100 parts by mass or more, further more preferably 120 parts by mass or more with respect to 100 parts by mass of the matrix resin. Also, a volume ratio of the solder particles in the bonding sheet 10 is preferably 5% by volume or more, more preferably 10% by volume or more, further more preferably 15% by volume or more. These configurations are preferable to ensure the cohesiveness of the solder particles in the bonding sheet 10 during the solder bonding process. Also, the solder particle content in the bonding sheet 10 is preferably 600 parts by mass or less, more preferably 450 parts by mass or less, further more preferably 170 parts by mass or less with respect to 100 parts by mass of the matrix resin. Also, the volume ratio of the solder particles in the bonding sheet 10 is preferably 80% by volume or less, more preferably 50% by volume or less, further more preferably 30% by volume or less. These configurations are preferable from the viewpoint of easy fabrication (moldability) of the bonding sheet 10 as a sheet member.

The fluxing agent is a component which develops an oxide film removal function with respect to the solder particles in the bonding sheet 10 during heating for solder bonding, and the solder particles are appropriately melted and aggregated by the oxide film removal.

Examples of a material of the fluxing agent include organic acids, quinolinol derivatives, and metal carbonyl acid salts. Examples of the organic acid include carboxylic acids. Examples of the carboxylic acid include monocarboxylic acid, dicarboxylic acid, and tricarboxylic acid. Examples of the monocarboxylic acid include glycolic acid, lactic acid, and 2-hydroxybutanoic acid. Examples of the dicarboxylic acid include tartaric acid, malic acid, adipic acid, malonic acid, succinic acid, glutaric acid, pimelic acid, suberic acid, and sebacic acid. An example of the tricarboxylic acid include citric acid. These fluxing agents may be used alone or in combination of two or more. From the viewpoint of the oxide film removal function, the fluxing agent is preferably carboxylic acid, more preferably dicarboxylic acid, further more preferably malic acid, adipic acid, and malonic acid, particularly preferably malic acid and malonic acid.

From the viewpoint of moldability of the bonding sheet 10, the fluxing agent is preferably solid at 25° C. The melting point of the fluxing agent is higher than 25° C., preferably 80° C. or more, more preferably 100° C. or more, further more preferably 120° C. or more. The melting point of the fluxing agent is, for example, 200° C. or less, preferably 180° C. or less, more preferably 160° C. or less. From the viewpoint of achieving both the moldability of the bonding sheet 10 and the above-described oxide film removal function, the fluxing agent is preferably a solid carboxylic acid at 25° C.

The fluxing agent content in the bonding sheet 10 is, for example, 10 parts by mass or more, preferably 30 parts by mass or more, more preferably 40 parts by mass or more with respect to 100 parts by mass of the matrix resin. Also, a volume ratio of the fluxing agent in the bonding sheet 10 is, for example, 10% by volume or more, preferably 20% by volume or more, more preferably 30% by volume or more. These configurations are preferable to ensure the cohesiveness of the solder particles in the bonding sheet 10 during the solder bonding process.

Also, the fluxing agent content in the bonding sheet 10 is, for example, 100 parts by mass or less, preferably 80 parts by mass or less, more preferably 60 parts by mass or less, further more preferably less than 50 parts by mass with respect to 100 parts by mass of the matrix resin. Also, the volume ratio of the fluxing agent in the bonding sheet 10 is, for example, 100% by volume or less, preferably 80% by volume or less, more preferably 50% by volume or less. These configurations are preferable from the viewpoint of moldability of the bonding sheet 10.

The matrix resin contains a thermosetting resin and a thermoplastic resin in the present embodiment. From the viewpoint of moldability of the bonding sheet 10, the thermosetting resin is preferably liquid at normal temperature before curing, and the thermoplastic resin is solid at normal temperature.

Examples of the thermosetting resin include epoxy resins, oxetane resins, thermosetting (meth)acrylic resins, diallyl phthalate resins, thermosetting polyesters, and maleimide resins. These thermosetting resins may be used alone or in combination of two or more. Preferably, an epoxy resin which is liquid at normal temperature before curing is used.

Examples of the epoxy resin include bisphenol epoxy resins, novolac epoxy resins, naphthalene epoxy resins, fluorene epoxy resins, triphenylmethane epoxy resins, glycidyl ether epoxy resins, and glycidylamine epoxy resins. Examples of the bisphenol epoxy resin include bisphenol A type epoxy resin, bisphenol F type epoxy resin, bisphenol S type epoxy resin, hydrogenated bisphenol A type epoxy resin, and dimer acid modified bisphenol epoxy resin. Examples of the novolac epoxy resin include phenol novolac epoxy resin, cresol novolac epoxy resin, and biphenyl epoxy resin. An example of the fluorene epoxy resin include bisarylfluorene epoxy resin. An example of the triphenylmethane epoxy resin include trishydroxyphenylmethane epoxy resin. As the epoxy resin, preferably, a bisphenol epoxy resin is used, more preferably, a bisphenol A type epoxy resin is used.

An epoxy equivalent of the epoxy resin is, for example, 80 g/eq or more, preferably 100 g/eq or more, and for example, 500 g/eq or less, preferably 400 g/eq or less.

A temperature at which the thermosetting resin cures is, for example, 90° C. or more, preferably 140° C. or more, and for example, 250° C. or less, preferably 230° C. or less.

A ratio of the thermosetting resin in the matrix resin is preferably 50% by mass or more, more preferably 60% by mass or more, and preferably 90% by mass or less, more preferably 80% by mass or less. A ratio of the thermosetting resin in the bonding sheet 10 is preferably 30% by volume or more, more preferably 40% by volume or more, and preferably 70% by volume or less, more preferably 60% by volume or less. These configurations are preferable to achieve both the moldability of the bonding sheet 10 and the bonding strength with respect to an object to be bonded of the bonding sheet 10 through the solder bonding process to be described later.

When the epoxy resin is used as the thermosetting resin, the matrix resin may further contain a phenol resin as a curing agent of the epoxy resin. Examples of the phenol resin include novolac phenol resins and resol phenol resins. Examples of the novolac phenol resin include phenol novolac resins, phenol aralkyl resins, cresol novolac resins, tert-butylphenol novolac resins, and nonylphenol novolac resins.

Examples of the thermoplastic resin include acrylic resins, styrene-butadiene-styrene copolymers, polybutadiene rubber, phenoxy resins, polyester resins, thermoplastic polyurethane, thermoplastic polyimide, thermoplastic polyamide, and polyacetal resins. These thermoplastic resins may be used alone or in combination of two or more. As the thermosetting resin, preferably, an acrylic resin is used.

The acrylic resin is a polymer of monomer components including alkyl (meth)acrylate. “(Meth)acrylate” means acrylate and/or methacrylate.

An example of the alkyl (meth)acrylate include an alkyl (meth)acrylate having a linear or branched alkyl group having 1 to 20 carbon atoms. Examples of the alkyl (meth)acrylate include methyl (meth)acrylate, ethyl (meth)acrylate, propyl (meth)acrylate, n-butyl (meth)acrylate, isopropyl (meth)acrylate, isobutyl (meth)acrylate, s-butyl (meth)acrylate, t-butyl (meth)acrylate, pentyl (meth)acrylate, isopentyl (meth)acrylate, neopentyl (meth)acrylate, hexyl (meth)acrylate, heptyl (meth)acrylate, 2-ethylhexyl (meth)acrylate, octyl (meth)acrylate, isooctyl (meth)acrylate, nonyl (meth)acrylate, isononyl (meth)acrylate, decyl (meth)acrylate, isodecyl (meth)acrylate, undecyl (meth)acrylate, dodecyl (meth)acrylate, isotridecyl (meth)acrylate, tetradecyl (meth)acrylate, isotetradecyl (meth)acrylate, pentadecyl (meth)acrylate, hexadecyl (meth)acrylate, heptadecyl (meth)acrylate, octadecyl (meth)acrylate, isooctadecyl (meth)acrylate, nonadecyl (meth)acrylate, and eicosyl (meth)acrylate. These alkyl (meth)acrylates may be used alone or in combination of two or more.

A ratio of the alkyl (meth)acrylate in the monomer component is preferably 70% by mass or more, more preferably 80% by mass or more, further more preferably 90% by mass or more. Also, the ratio of the alkyl (meth)acrylate in the monomer component is preferably 99.5% by mass or less, more preferably 99% by mass or less.

The monomer component may include a copolymerizable monomer which is copolymerizable with alkyl (meth)acrylate.

Examples of the copolymerizable monomer include polar group-containing vinyl monomers. The polar group-containing vinyl monomer serves to modify the acrylic resin such as ensuring cohesive force of the acrylic resin. Examples of the polar group-containing vinyl monomer include hydroxy group-containing vinyl monomers, carboxy group-containing vinyl monomers, acid anhydride vinyl monomers, sulfo group-containing vinyl monomers, phosphoric acid group-containing vinyl monomers, cyano group-containing vinyl monomers, and glycidyl group-containing vinyl monomers, and preferably, a hydroxy group-containing vinyl monomer is used.

Examples of the copolymerizable monomer also include aromatic vinyl monomers. The aromatic vinyl monomer serves to solidify the acrylic resin at normal temperature. Examples of the aromatic vinyl monomer include styrene, chloro styrene, chloromethylstyrene, and α-methylstyrene, and preferably, styrene is used.

These copolymerizable monomers may be used alone or in combination of two or more.

A ratio of the copolymerizable monomer in the monomer component is preferably 0.1% by mass or more, more preferably 0.5% by mass or more, further more preferably 1.5% by mass or more from the viewpoint of ensuring an effect by using the copolymerizable monomer. The ratio of the copolymerizable monomer in the monomer component is preferably 10% by mass or less, more preferably 5% by mass or less, further more preferably 3% by mass or less.

The acrylic resin can be formed by polymerizing the above-described monomer component. Examples of the polymerization method include solution polymerization, bulk polymerization, and emulsion polymerization, and preferably, solution polymerization is used.

A weight average molecular weight Mw of the acrylic resin is, for example, 8000 or more, preferably 10000 or more, and for example, 2 million or less, preferably 1.5 million or less. The Mw (value in terms of standard polystyrene) of the acrylic resin is calculated by GPC.

A glass transition temperature Tg of the acrylic resin is preferably 30° C. or more, more preferably 50° C. or more, and for example, 100° C. or less, preferably 50° C. or less.

As for the glass transition temperature (Tg) of the polymer, a glass transition temperature (theoretical value) determined based on the following Fox equation can be used. The Fox equation is a relational expression between the glass transition temperature Tg of a polymer and a glass transition temperature Tgi of a homopolymer of a monomer constituting the polymer. In the following Fox equation, Tg represents the glass transition temperature (° C.) of the polymer, Wi represents a weight fraction of a monomer i constituting the polymer, and Tgi represents the glass transition temperature (° C.) of the homopolymer formed from the monomer i. Literature values can be used for the glass transition temperature of the homopolymer, and for example, in “Polymer Handbook” (4th edition, John Wiley & Sons, Inc., 1999) and “New Polymer Library 7 Introduction to Synthetic Resin for Paints” (written by Kyozo Kitaoka, Polymer Publication Society, 1995), the glass transition temperatures of various homopolymers are listed. On the other hand, the glass transition temperature of the homopolymer of the monomer can also be determined by the method specifically described in Japanese Unexamined Patent Publication No. 2007-51271.

1/(273+Tg)=Σ[Wi/(273+Tgi)] Fox equation

A ratio of the thermoplastic resin in the matrix resin is preferably 10% by mass or more, more preferably 20% by mass or more, and preferably 50% by mass or less, more preferably 40% by mass or less. A ratio of the thermoplastic resin in the bonding sheet 10 is preferably 2% by volume or more, more preferably 5% by volume or more, further more preferably 10% by volume or more, and preferably 50% by volume or less, more preferably 30% by volume or less, further more preferably 20% by volume or less. These configurations are preferable to achieve both the moldability of the bonding sheet 10 and the bonding strength with respect to an object to be bonded of the bonding sheet 10 through the solder bonding process to be described later.

The matrix resin may contain a thermosetting catalyst. The thermosetting catalyst is a catalyst which promotes curing of the thermosetting resin by heating. Examples of the thermosetting catalyst include imidazole compounds, triphenylphosphine compounds, amine compounds, and trihalogen borane compounds. Examples of the imidazole compound include 2-methylimidazole, 2-undecylimidazole, 2-heptadecylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, and 1-cyanoethyl-2-undecylimidazole. Examples of the triphenylphosphine compound include triphenylphosphine, tributylphosphine, diphenyltolylphosphine, tetraphenylphosphonium bromide, methyltriphenylphosphonium bromide, methyltriphenylphosphonium chloride, methoxymethyltriphenylphosphonium, and benzyltriphenylphosphonium chloride. Examples of the amine compound include monoethanolamine trifluoroborate and dicyandiamide. An example of the trihalogen borane compound includes trichloroborane. These thermosetting catalysts may be used alone or in combination of two or more. As the thermosetting catalyst, preferably, an imidazole compound is used, more preferably, 1-benzyl-2-phenylimidazole is used.

When the thermosetting catalyst is used, a blending amount of the thermosetting catalyst is preferably 0.1 parts by mass or more, more preferably 1 part by mass or more, and preferably 7 parts by mass or less, more preferably 5 parts by mass or less with respect to 100 parts by mass of the thermosetting resin.

A content ratio of the matrix resin in the bonding sheet 10 is preferably 40% by volume or more, more preferably 55% by volume or more, and preferably 80% by volume or less, more preferably 70% by volume or less. Such a configuration is preferable to balance easy aggregation of a melted solder and easy formation of solder portions isolated from each other during the heating process in the solder bonding.

The bonding sheet 10 may also contain another component if necessary. Examples of the other component include colorants and coupling agents.

Examples of the colorant include black colorants, cyan colorants, magenta colorants, and yellow colorants. The colorant may be a pigment or a dye.

As the colorant, a black colorant is preferable from the viewpoint of ensuring engraving by laser marking or the like. Examples of the black colorant include carbon black, copper oxide, manganese dioxide, aniline black, perylene black, titanium black, and cyanine black. Further, as the colorant, a compound which is colored by radiation irradiation such as ultraviolet rays may also be used. Examples of the compound include leuco dyes. These colorants may be used alone or in combination of two or more. When the bonding sheet 10 contains the colorant, a content ratio of the colorant in the bonding sheet 10 is, for example, 0.01% by mass or more, and for example, 1% by mass or less.

A thickness of the bonding sheet 10 is, for example, 50 μm or less, preferably 30 μm or less, more preferably 25 μm or less, further more preferably 20 μm or less, particularly preferably 15 μm or less. The thinner the bonding sheet 10, the easier to cope with a fine pitch of a bump forming portion. The thickness of the bonding sheet 10 is preferably 3 μm or more, more preferably 5 μm or more from the viewpoint of handleability of the bonding sheet 10.

The bonding sheet 10 has a surface 10a with a surface roughness Sa of 2.5 μm or less. The surface roughness Sa is preferably 1.5 μm or less, more preferably 1 μm or less, further more preferably 0.7 μm or less, particularly preferably less than 0.5 μm. The surface roughness Sa is a three-dimensional arithmetic average roughness, and is determined by a method to be described later regarding Examples. The surface roughness Sa is, for example, 0.01 μm or more.

The bonding sheet 10 has a tack change rate, from the same bonding sheet (reference bonding sheet) except for not containing the above-described fluxing agent, of preferably −30% or more, more preferably −20% or more, further more preferably −15% or more, even more preferably −5% or more, even more preferably 0% or more. (the tack change rate is the ratio of change in the tack of the bonding sheet 10 with respect to the tack of the reference bonding sheet). Such a configuration is preferable to ensure adhesive strength in the bonding sheet 10 when bonded to an adherend.

The bonding sheet 10 can be produced by the following production method. This production method is one embodiment of a production method of the bonding sheet of the present invention.

First, the above-described fluxing agent is dissolved in a first solvent to prepare a fluxing agent solution (first step). The first solvent is a solvent capable of dissolving a fluxing agent and is selected according to the kind of fluxing agent. The fluxing agent can also be used in powder form without dissolving in a solvent.

The first solvent is not limited as long as it is a solvent in which the fluxing agent is dissolved. Examples of the first solvent include polar solvents and low polar solvents. Examples of the polar solvent include water, alcohols, and carboxylic acids. Examples of the alcohol include methanol, ethanol, isopropyl alcohol, and butanol. Examples of the carboxylic acid include formic acid and acetic acid. Examples of the low polar solvent include methyl ethyl ketone and methyl isobutyl ketone. When a solid carboxylic acid at normal temperature is used as the fluxing agent, as the first solvent, preferably, a polar solvent is used, more preferably, an alcohol is used, and further more preferably, ethanol is used.

The particle size D₅₀ of the fluxing agent used in this step is not particularly limited, and is, for example, 10 nm or more, and for example, 100 μm or less. In the present production method, even relatively large flux particles can be appropriately used as the fluxing agent because the fluxing agent is dissolved in the first solvent in this step.

The fluxing agent solution has a fluxing agent concentration (non-volatile component concentration) of preferably 10% by mass or more, more preferably 20% by mass or more, further more preferably 25% by mass or more, and preferably 50% by mass or less, more preferably 40% by mass or less, further more preferably 35% by mass or less from the viewpoint of mixing with another component in the following second step.

In the present production method, a second solvent is then mixed with the above-described matrix resin components (thermosetting resin, thermoplastic resin, and another component which is blended if necessary), the solder particles, and the fluxing agent solution to prepare a mixed composition (second step). The second solvent is a solvent of a different kind from the first solvent and is lower in polarity than the first solvent. The second solvent is preferably a solvent in which at least a portion of the fluxing agent is dissolved. Examples of the second solvent include ketones, alkyl esters, aliphatic hydrocarbons, and aromatic hydrocarbons. Examples of the ketones include acetone, methyl ethyl ketone, methyl isobutyl ketone, and cyclohexanone. Examples of the alkyl esters include methyl acetate, ethyl acetate, butyl acetate, isobutyl acetate, and amyl acetate. Examples of the aliphatic hydrocarbons include n-hexane, n-heptane, octane, cyclohexane, and methylcyclohexane. Examples of the aromatic hydrocarbons include toluene, xylene, and ethylbenzene. These second solvents may be used alone or in combination of two or more. The mixed composition has a solids concentration of preferably 50% by mass or more, more preferably 60% by mass or more, further more preferably 65% by mass or more, and preferably 80% by mass or less, more preferably 75% by mass or less from the viewpoint of easy formation of a coated film in the following third step.

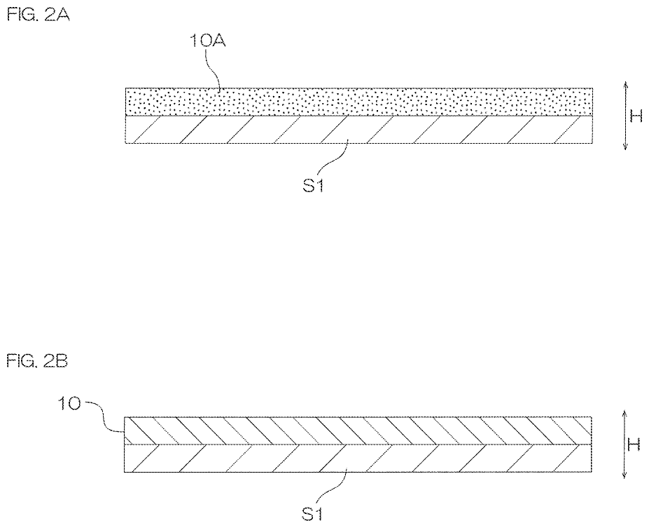

Next, as shown in FIG. 2A, a coating of the mixed composition is applied onto the substrate S1 to form a coated film 10A, and, as shown in FIG. 2B, the coated film 10A is dried to form the bonding sheet 10 (third step). An example of the substrate S1 includes a plastic film. Examples of the plastic film include polyethylene terephthalate films, polyethylene films, polypropylene films, and polyester films. The substrate preferably has a surface subjected to a surface release treatment.

In this step, the bonding sheet 10 is preferably dried by heating. A drying temperature is a softening temperature of the thermoplastic resin or more, below the melting point of the solder particles and the fluxing agent, and below a curing temperature of the thermosetting resin. The drying temperature is preferably 60° C. or more, more preferably 75° C. or more, and preferably 130° C. or less, more preferably 120° C. or less.

Before or after the third step, the substrate S2 may be laminated on top of the bonding sheet 10 on the substrate S1. As the substrate S2, the above-described plastic films for the substrate S1 can be used (the state in which the bonding sheet 10 is sandwiched between the substrates S1 and S2 is illustrated in FIG. 1).

As described above, the bonding sheet 10 can be produced.

In the present production method, as described above, the fluxing agent is dissolved in the first solvent in the first step. In the second step, the fluxing agent is mixed with other components (matrix resin components and solder particles) in the state of being dissolved in the first solvent. In the third step, first, a coated film is formed on the substrate S1 from the mixed composition containing the fluxing agent in the dissolved state. In this coated film, surface unevenness resulting from the inclusion of the fluxing agent is suppressed. Therefore, surface unevenness resulting from the inclusion of the fluxing agent is also suppressed in the bonding sheet 10 formed by drying the coated film. This production method of the bonding sheet is suitable for producing the bonding sheet 10 that contains the matrix resin, the solder particles, and the fluxing agent, and that has the surface 10a with a surface roughness Sa of 2.5 μm or less.

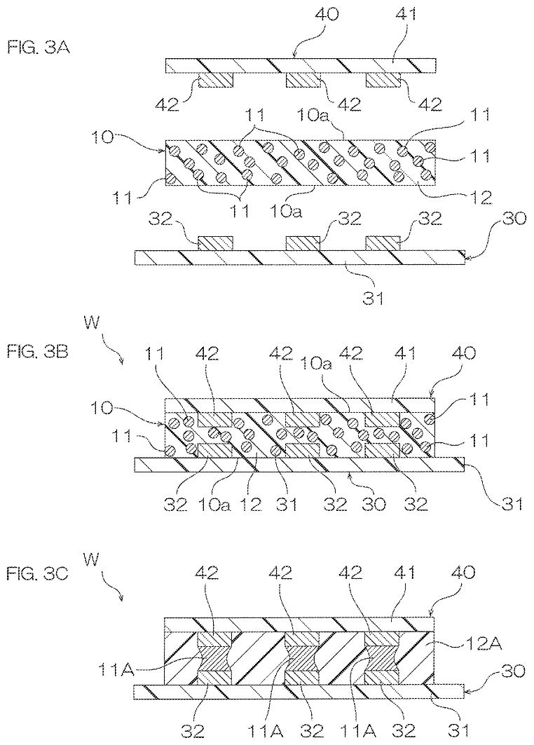

FIG. 3 shows one example of a solder bonding method using the bonding sheet 10.

In the present method, first, as shown in FIG. 3A, a wiring board 30, an electronic component 40, and the bonding sheet 10 are prepared (preparation step). The wiring board 30 is one example of one object to be bonded, and has a substrate 31 and a plurality of terminals 32. The substrate 31 is, for example, an insulating substrate having a flat plate shape. The terminal 32 is made of metal. The plurality of terminals 32 are isolated from each other. The maximum length of the terminal 32 is, for example, 10 μm or more, and for example, 200 μm or less. An interval between the terminals 32 is, for example, 10 μm or more, and for example, 200 μm or less. The electronic component 40 is one example of the other object to be bonded, and has a body portion 41 whose surface is resin-sealed and a plurality of terminals 42 which are electrically connected to the inside of the component. The terminal 42 is made of metal. The plurality of terminals 42 are isolated from each other. The plurality of terminals 42 are provided in an arrangement and size that can face the plurality of terminals 32 of the wiring board 30. For the bonding sheet 10, solder particles 11 and a matrix resin 12 are illustrated.

Next, as shown in FIG. 3B, the wiring board 30, the bonding sheet 10, and the electronic component 40 are laminated in this order (lamination step). Specifically, the wiring board 30 and the electronic component 40 are compressively bonded via the bonding sheet 10 so that the respective terminals 32 and 42 face each other, and the terminals 32 and 42 are buried in the bonding sheet 10. Thus, a laminate W is obtained.

The wiring board 30 and the electronic component 40 are temporarily bonded via the bonding sheet 10.

Next, by heating the laminate W, as shown in FIG. 3C, a solder portion 11A is formed between each of the terminals 32 and 42 (heating step). A heating temperature is the melting point of the solder particles 11 and the fluxing agent or more, the softening point of the thermoplastic resin or more, and the curing temperature of the thermosetting resin or more. The heating temperature is appropriately determined in accordance with the kind of the thermosetting resin, the thermoplastic resin, the solder particles, and the fluxing agent, and is, for example, 120° C. or more, preferably 130° C. or more, and for example, 170° C. or less, preferably 160° C. or less. Further, the heating time is, for example, 3 seconds or more, and for example, 30 seconds or less, preferably 20 seconds or less.

By the short-time heating as described above in the heating step, in the bonding sheet 10, the thermoplastic resin is melted once, and the fluxing agent is melted to develop the oxide film removal function of the surfaces of the solder particles. Then, the solder particles are melted and aggregated, and then gather between the terminals 32 and 42 (self-alignment), so that curing of the thermosetting resin progresses around the solder where the particles gather. By lowering the temperature after the completion of the heating step, the solder material which aggregates between the terminals 32 and 42 coagulates, thereby forming the solder portion 11A. Thus, the terminals 32 and 42 are electrically connected by the solder portion 11A, while the wiring board 30 is bonded to the electronic component 40 by the bonding sheet 10. A cured resin portion 12A derived from the matrix resin 12 is formed around the solder portion 11A.

The cured resin portion 12A contains a thermosetting resin in which the curing progresses at least partially and a solidified thermoplastic resin, and preferably contains a thermosetting resin in a fully cured state and a solidified thermoplastic resin.

As described above, it is possible to mount the electronic component 40 on the wiring board 30 using the bonding sheet 10.

As described above, the surface roughness Sa of the surface 10a of the bonding sheet 10 is 2.5 μm or less, preferably 1.5 μm or less, more preferably 1 μm or less, further more preferably 0.7 μm or less. Such a configuration is suitable for ensuring adhesive strength during temporary bonding (FIG. 3B) of the adherend (wiring board 30, electronic component 40) by the bonding sheet 10, and thus is suitable for suppressing adhesive failure to the adherend.

On the other hand, during the above-described temporary bonding, the larger the surface unevenness of the bonding sheet 10, the more easily a void (partial air gap) is formed between the adherend and the bonding sheet 10. The formation of the void causes failure to form the above-described solder portion 11A and cured resin portion 12A, which is not preferable. The above-described configuration regarding the surface roughness Sa is suitable for suppressing the formation of void between the adherend and the bonding sheet 10 during temporary bonding. The suppression of void helps to suppress adhesion failure to the adherend.

### EXAMPLE

### Example 1

A bonding sheet of Example 1 was fabricated as follows.

First, as a fluxing agent, malic acid (particle size D₅₀ of 4.4 μm) was added to ethanol and dissolved to prepare a fluxing agent solution having a solids concentration (non-volatile component concentration) of 33% by mass (first step).

Then, as a thermosetting resin, 70 parts by mass of an epoxy resin (trade name “jER828”, bisphenol A type epoxy resin, epoxy equivalent of 184 to 194 g/eq, liquid at normal temperature, manufactured by Mitsubishi Chemical Corporation); as a thermoplastic resin, 30 parts by mass of an acrylic resin (trade name “ARUFON UH-2170”, hydroxy group-containing styrene acrylic polymer, solid at normal temperature, manufactured by Toagosei Co., Ltd.); 150 parts by mass of solder particles (42% by mass of Sn-58% by mass of Bi alloy, melting point of 139° C., spherical shape, particle size D₅₀ of 3 μm); and a fluxing agent solution were added to methyl ethyl ketone (MEK) to be mixed, thereby preparing a mixed composition having a solids concentration of 70% by mass (second step). The fluxing agent content in this mixed composition is 50 parts by mass.

Next, a coating of the mixed composition was applied onto a separator to form a coated film, and the coated film was then dried (third step). The drying temperature was 80° C., and the drying time was 3 minutes. Thus, a bonding sheet having a thickness of 10 μm was formed on the separator. The composition of the bonding sheet of Example 1 is shown in Table 1 (the compositions of the bonding sheets of the following Examples and Comparative Examples are also shown in Tables 1 and 2). In Tables 1 and 2, the unit of each numerical value representing the composition is relative “parts by mass”.

### Example 2

A bonding sheet of Example 2 was fabricated in the same manner as the bonding sheet of Example 1, except that in the second step, the blending amount of the fluxing agent (malic acid) in the mixed composition was changed to 25 parts by mass instead of 50 parts by mass.

### Example 3

A bonding sheet of Example 3 was fabricated in the same manner as the bonding sheet of Example 1, except that in the third step, the thickness of the bonding sheet was changed to 20 μm instead of 10 μm.

### Example 4

A bonding sheet of Example 4 was fabricated in the same manner as the bonding sheet of Example 1, except that in the first step, malonic acid was used instead of the malic acid as the fluxing agent; and in the second step, the fluxing agent content in the mixed composition was 25 parts by mass.

### Example 5

A bonding sheet of Example 5 was fabricated in the same manner as the bonding sheet of Example 1, except that in the first step, malonic acid was used instead of the malic acid as the fluxing agent; in the second step, the fluxing agent content in the mixed composition was 25 parts by mass; and in the third step, a bonding sheet having a thickness of 20 μm was formed on the separator.

### Example 6

A bonding sheet of Example 6 was fabricated in the same manner as the bonding sheet of Example 1, except that in the first step, malonic acid was used instead of the malic acid as the fluxing agent; in the second step, the fluxing agent content in the mixed composition was 10 parts by mass; and in the third step, a bonding sheet having a thickness of 20 μm was formed on the separator.

### Examples 7 to 10

Bonding sheets of Examples 7 to 10 were fabricated in the same manner as the bonding sheet of Example 1, except that in the first step, instead of the malic acid as the fluxing agent, adipic acid was used in powder form without being dissolved in ethanol; in the second step, the epoxy resin as the thermosetting resin, the acrylic resin as the thermoplastic resin, the solder particles, and the fluxing agent solution were mixed first, and a predetermined amount of methyl ethyl ketone (MEK) listed in Table 2 was then added thereto and mixed, thereby preparing a coating liquid (second step), and the fluxing agent content in the mixed composition was 25 parts by mass; and in the third step, a bonding sheet having a thickness of 20 μm was formed on the separator.

### Comparative Example 1

A bonding sheet of Comparative Example 1 was fabricated in the same manner as in Example 1, except the following: In the first step, adipic acid (particle size D₅₀ of 4.5 μm) was used as the fluxing agent instead of malic acid, and the adipic acid was not dissolved in ethanol.

### Comparative Example 2

A bonding sheet of Comparative Example 2 was fabricated in the same manner as in Example 1, except the following: In the first step, adipic acid (particle size D₅₀ of 4.5 μm) was used as the fluxing agent instead of malic acid, and the adipic acid was not dissolved in ethanol. In the second step, the blending amount of the fluxing agent in the mixed composition was changed to 25 parts by mass instead of 50 parts by mass.

### Comparative Example 3

A bonding sheet of Comparative Example 3 was fabricated in the same manner as in Example 1, except the following: In the first step, adipic acid (particle size D₅₀ of 4.5 μm) was used as the fluxing agent instead of malic acid, and the adipic acid was not dissolved in ethanol. In the second step, the blending amount of the fluxing agent in the mixed composition was changed to 25 parts by mass instead of 50 parts by mass. In the third step, the thickness of the bonding sheet was changed to 20 μm instead of 10 μm.

### Comparative Example 4

A bonding sheet of Comparative Example 4 was fabricated in the same manner as the bonding sheet of Example 1, except that in the first step, instead of the malic acid as the fluxing agent, adipic acid was used in powder form without being dissolved in ethanol; in the second step, the epoxy resin as the thermosetting resin, the acrylic resin as the thermoplastic resin, the solder particles, and the fluxing agent solution were mixed first, and a predetermined amount of methyl ethyl ketone (MEK) listed in Table 2 was then added thereto and mixed, thereby preparing a coating liquid (second step), and the fluxing agent content in the mixed composition was 25 parts by mass; and in the third step, a bonding sheet having a thickness of 20 μm was formed on the separator.

### Reference Example 1

A bonding sheet (thickness of 10 μm) of Reference Example 1 was fabricated in the same manner as the bonding sheets of Examples 1, 2, 4 and Comparative Examples 1 and 2, except that the fluxing agent was not used. The bonding sheet of Reference Example 1 corresponds to the same bonding sheet as the bonding sheets of Examples 1, 2, 4 and Comparative Examples 1 and 2, except that it does not contain the fluxing agent.

### Reference Example 2

A bonding sheet (thickness of 20 μm) of Reference Example 2 was fabricated in the same manner as the bonding sheets of Examples 3, 5 to 10 and Comparative Examples 3 and 4, except that the fluxing agent was not used. The bonding sheet of Reference Example 2 corresponds to the same bonding sheet as the bonding sheets of Examples 3, 5 to 10 and Comparative Examples 3 and 4, except that it does not contain the fluxing agent.

### <Surface Roughness>

The surface roughness of each of the bonding sheets of Examples 1 to 10, Comparative Examples 1 to 4, and Reference Examples 1 and 2 was measured. Specifically, first, a measurement sample having a size of 5 cm×5 cm was cut out from the bonding sheet with the separator. Then, an exposed surface of the bonding sheet in the measurement sample was photographed by a laser microscope (trade name “VK-1000,” manufactured by Keyence Corporation). In the photographing, a 20× lens was used and the measurement mode was set to a confocal mode (ISO 25178-607). The surface roughness Sa (μm) of a given area (300 μm×300 μm) was then calculated based on the photographed data. The resulting values are shown in Tables 1 and 2.

### <Tack>

The tack of each of the bonding sheets of Examples 1 to 10, Comparative Examples 1 to 4, and Reference Examples 1 and 2 was measured as follows.

First, a test piece for measurement was prepared. Specifically, first, a double-sided adhesive tape (trade name “No. 5000NS”, manufactured by Nitto Denko Corporation) was attached to a polyester film (trade name “Lumirror”, thickness of 50 μm, manufactured by Toray Industries, Inc.). Then, the bonding sheet was attached to the double-sided adhesive tape to obtain a laminate. A 2 kg hand roller was used for such attachment. Then, a test piece having a size of 2 cm×2 cm was cut out from the laminate.

Next, the tack (N) of the surface of the bonding sheet in the test piece was measured by a tackiness tester (trade name “TAC1000”, manufactured by Rhesca Co, Ltd.). This measurement was performed using a SUS403 probe (diameter of 5 mm) at a pressing speed of 0.5 mm/sec at a pressing pressure of 0.5 N at a pressing time of 1.5 seconds at a peeling speed of 2 mm/sec. The measurement results are shown in Tables 1 and 2.

The rate of change in the tack (T₂) of each of the bonding sheets (thickness of 10 μm) of Examples 1, 2, 4 and Comparative Examples 1 and 2 relative to the tack (T₁) of the bonding sheet (thickness of 10 μm) of Reference Example 1 (first tack change rate), and the rate of change in the tack (T₄) of each of the bonding sheets (thickness of 20 μm) of Examples 3, 5 to 10 and Comparative Examples 3 and 4 relative to the tack (T₃) of the bonding sheet (thickness of 10 μm) of Reference Example 2 (second tack change rate) are also shown in Tables 1 and 2. The first tack change rate is represented by (T₂−T₁)/T₁. The above-described first tack change rate of each of the bonding sheets of Examples 1, 2, 4 and Comparative Examples 1 and 2 is a tack change rate from the same bonding sheet of Reference Example 1 except for not containing the fluxing agent. The second tack change rate is represented by (T₄−T₃)/T₃. The above-described second tack change rate of each of the bonding sheets of Examples 3, 5 to 10 and Comparative Examples 3 and 4 is a tack change rate from the same bonding sheet of Reference Example 2 except for not containing the fluxing agent.

The first tack change rate of each of the bonding sheets of Examples 1, 2, and 4, and the second tack change rate of each of the bonding sheets of Examples 3, 5 to 10 are −30% or more, and in the bonding sheets of Examples 1 to 10, the tack reduction due to the presence of the fluxing agent is suppressed, and excellent adhesiveness is ensured. In contrast to this, the first tack change rate of each of the bonding sheets of Comparative Examples 1 and 2, and the second tack change rate of each of the bonding sheets of Comparative Examples 3 and 4 are less than −30%, and in the bonding sheets of Comparative Examples 1 to 4, the tack reduction due to the presence of the fluxing agent is not suppressed, and excellent adhesiveness is not ensured.

TABLE 1

| | | Ex. | Ex. | Ex. | Comp. | Comp. | Comp. | Ref. | Ref. |
|---|---|---|---|---|---|---|---|---|---|
| | | 1 | 2 | 3 | Ex. 1 | Ex. 2 | Ex. 3 | Ex. 1 | Ex. 2 |
| Epoxy resin (liquid at normal temperature) | | 70 | 70 | 70 | 70 | 70 | 70 | 70 | 70 |
| Acrylic resin (solid at normal temperature) | | 30 | 30 | 30 | 30 | 30 | 30 | 30 | 30 |
| Solder particles (Sn—Bi, D₅₀ 3 μm) | | 150 | 150 | 150 | 150 | 150 | 150 | 150 | 150 |
| Fluxing | Malic acid blended by | 50 | 25 | 50 | — | — | — | — | — |
| agent | dissolving | | | | | | | | |
| | Adipic acid blended in | — | — | — | 50 | 25 | 25 | — | — |
| | powder form | | | | | | | | |

| | | | | | | | | |
|---|---|---|---|---|---|---|---|---|
| Thickness (μm) | 10 | 10 | 20 | 10 | 10 | 20 | 10 | 20 |
| Surface roughness Sa (μm) | 0.2 | 0.5 | 0.2 | 3.1 | 2.6 | 2.7 | 0.2 | 0.2 |
| Tack (N) | 1.21 | 1.26 | 1.35 | 0.82 | 0.83 | 1.00 | 1.41 | 1.55 |
| Tack change rate (%) | −14 | −11 | −13 | −42 | −41 | −35 | | |

TABLE 2

| | | Ex. | Ex. | Ex. | Comp. | Ex. | Ex. | Ex. | Ex. |
|---|---|---|---|---|---|---|---|---|---|
| | | 4 | 5 | 6 | Ex. 4 | 7 | 8 | 9 | 10 |
| Epoxy resin (liquid at normal temperature) | | 70 | 70 | 70 | 70 | 70 | 70 | 70 | 70 |
| Acrylic resin (solid at normal temperature) | | 30 | 30 | 30 | 30 | 30 | 30 | 30 | 30 |
| Solder particles (Sn—Bi, D₅₀ 3 μm) | | 150 | 150 | 150 | 150 | 150 | 150 | 150 | 150 |
| Fluxing | Malic acid blended by | — | — | — | — | — | — | — | — |
| agent | dissolving | | | | | | | | |
| | Adipic acid blended in | — | — | — | 25 | 25 | 25 | 25 | 25 |
| | powder form | | | | | | | | |
| | Malonic acid blended by | 25 | 25 | 10 | — | — | — | — | — |
| | dissolving | | | | | | | | |

| | | | | | | | | |
|---|---|---|---|---|---|---|---|---|
| Dilution solvent (MEK) | — | — | — | 33 | 67 | 83 | 100 | 133 |
| Thickness (μm) | 10 | 20 | 20 | 20 | 20 | 20 | 20 | 20 |
| Surface roughness Sa (μm) | 0.7 | 0.5 | 0.7 | 2.8 | 2.0 | 1.7 | 1.4 | 1.0 |
| Tack (N) | 1.28 | 1.29 | 1.37 | 0.61 | 1.1 | 1.15 | 1.13 | 1.23 |
| Tack change rate (%) | −17 | −9 | −11 | −57 | −24 | −20 | −21 | −15 |

While the illustrative embodiments of the present invention are provided in the above-described invention, such is for illustrative purpose only and it is not to be construed restrictively. Modification and variation of the present invention that will be obvious to those skilled in the art is to be covered by the following claims.

### INDUSTRIAL APPLICABILITY

The bonding sheet of the present invention is suitably used, for example, in bonding a terminal of a wiring circuit board to a terminal of an electronic component, and in bonding between terminals of two wiring circuit boards.

### DESCRIPTION OF REFERENCE NUMERALS

10 bonding sheet
10a surface
H thickness direction
10A coated film
11 solder particles
11A solder portion
12 matrix resin
12A cured resin portion
S1, S2 substrate
30 wiring board
40 electronic component

1. A bonding sheet, comprising
a matrix resin; solder particles; and a fluxing agent, and
having a surface with a surface roughness Sa of 2.5 μm or less.

2. The bonding sheet according to claim 1, wherein the fluxing agent is a solid carboxylic acid at 25° C.

3. The bonding sheet according to claim 1, having a thickness of 30 μm or less.

4. The bonding sheet according to claim 1, having a tack change rate of −30% or more, the tack change rate from the same bonding sheet except for not containing the fluxing agent.
